(19) United States
(12) Patent Application Publication
(10) Pub. No.: US 2015/0149853 A1
(43) Pub. Date: May 28, 2015

(54) HALF PIPELINED TURBO DECODER AND METHOD FOR CONTROLLING THEREOF

(71) Applicant: Electronics and Telecommunications Research Institute, Daejeon (KR)

(72) Inventor: Min-Hyuk KIM, Daejeon (KR)

(73) Assignee: Electronics and Telecommunications Research Institute, Daejeon (KR)

(21) Appl. No.: 14/178,482

(22) Filed: Feb. 12, 2014

(30) Foreign Application Priority Data
Nov. 27, 2013 (KR) 10-2013-0145123

(51) Int. Cl. H03M 13/27

(52) U.S. Cl. CPC H03M 13/2775
USPC 714/756

(57) ABSTRACT

A turbo decoder configured to perform MAP (Maximum A Posteriori) decoding for a plurality of data blocks including encoded noise, comprises a first MAP decoder configured to perform MAP decoding for a first data block that is included in the plurality of data blocks; an interleaver configured to interleave a result of performing MAP decoding for the first data block; a second MAP decoder configured to perform MAP decoding based on a data included in the first data block and an interleaved data of the first data block; a deinterleaver configured to deinterleave a result of performing MAP decoding from the second MAP decoder for the first data block; and at least one storage unit configured to be formed between the first MAP decoder, the interleaver, the second MAP decoder and the deinterleaver.

### CROSS-REFERENCE TO RELATED APPLICATION

This application is based on and claims priority from Korean Patent Application No. 10-2013-0145123, filed on Nov. 27, 2013 in the Korean Intellectual Property Office, the disclosure of which is incorporated herein in its entirety by reference.

### BACKGROUND OF THE INVENTION

1. Field of the Invention

The present invention relates to half pipelined turbo decoder and method for controlling thereof, and more particularly, to half pipelined turbo decoder performing decoding function concurrently for a plurality of is data blocks and method for controlling thereof.

2. Description of the Related Art

Turbo decoder is the apparatus that enables improved decision by iterating the process of inputting soft decision output of decoder for component code to the rest of the decoder again.

It is difficult to implement such a turbo decoder using a pipelined architecture because the turbo decoder continually iterates the process of decoding a single data block.

Further, speeding the process of decoding is difficult because such a turbo decoder cannot perform the process of decoding the other data block until the process of decoding all of the single data block is finished.

### BRIEF SUMMARY OF THE INVENTION

An object of the present invention is to address at least the problems and/or disadvantages and to provide at least the advantages described below. An aspect of the present invention provides a turbo decoder of half pipelined scheme, the turbo decoder includes a first MAP decoder, an interleaver, a second MAP decoder and a deinterleaver and performs operation function for each of data block in half pipelined scheme.

Another aspect of the present invention provides a turbo decoder of half pipelined scheme, the turbo decoder includes at least one storage unit that is formed between a BM operation unit, a BSM operation unit and a FSM/LLR operation unit, and performs operation function for each of data block in half pipelined scheme, where the BM operation unit, the BSM operation unit and the FSM/LLR operation unit constitute a MAP decoder.

According to an aspect of the present invention, a turbo decoder adapted to perform MAP (Maximum A Posteriori) decoding for a plurality of data blocks including encoded noise, includes a first MAP decoder for performing MAP decoding for a first data block that is included in the plurality of data blocks; an interleaver for interleaving a result of performing MAP decoding for the first data block; a second MAP decoder for performing MAP decoding based on a data included in the first data block and an interleaved data of the first data block; a deinterleaver for deinterleaving a result of performing MAP decoding from the second MAP decoder for the first data block; and at least one storage unit adapted to be formed between the first MAP decoder, the interleaver, the second MAP decoder and the deinterleaver.

According to an aspect of the present invention, the turbo decoder may be adapted to perform operation concurrently for data blocks which are different each other based on a compartment that is formed on a front and a rear of the at least one storage unit.

According to an aspect of the present invention, wherein the at least one storage unit may include at least one of: a first storage unit formed between the first MAP decoder and the interleaver; a second storage unit formed between the interleaver and the second MAP decoder; a third storage unit formed between the second MAP decoder and the deinterleaver; and a fourth storage unit formed between the deinterleaver and the first MAP decoder.

According to an aspect of the present invention, wherein the first MAP decoder may perform MAP decoding for a second data block that is included in the plurality of data blocks, when the interleaver interleaves a result of performing MAP decoding for the first data block that is stored in the first storage unit.

According to an aspect of the present invention, when the second MAP decoder may perform MAP decoding for an interleaved data of the first data block that is included in the second storage unit, wherein the first MAP decoder performs MAP decoding for a third data block that is included in the plurality of data blocks, and the interleaver interleaves a result of MAP decoding for a second data block that is included in the plurality of data blocks stored in the first storage unit.

According to an aspect of the present invention, when the interleaver may interleave a result of performing MAP decoding for the first data block that is stored in the third storage unit, wherein the first MAP decoder performs MAP decoding for a fourth data block that is included in the plurality of data blocks, the interleaver interleaves a result of performing MAP decoding for a third data block that is included in the plurality of data blocks stored in the first storage unit, and the second MAP decoder performs MAP decoding for an interleaved data of a second data block that is included in the plurality of data blocks stored in the second storage unit.

According to an aspect of the present invention, the turbo decoder may further include a first delay element for outputting by delaying temporarily a deinterleaved data from the deinterleaver that is stored temporarily in the fourth storage unit; a second delay element for outputting by delaying temporarily an interleaved data from the interleaver that is stored temporarily in the second storage unit; and a third delay element for outputting by delaying temporarily a first data that is included in the first data block and includes encoded noise from an outside.

According to an aspect of the present invention, the turbo decoder may further include a first adder for adding the deinterleaved data from the deinterleaver that is stored in fourth storage unit and a second data that is included in the first data block and includes encoded noise from the outside; a second adder for adding a data temporarily delayed by the first delay element and a result of performing MAP decoding from the first MAP decoder for the first data block, and transmitting the added data to the first storage unit; and a third adder for adding a data temporarily delayed by the second delay element and a result of performing MAP decoding from the second MAP decoder for the first data block, and transmitting the added data to the third storage unit.

According to an aspect of the present invention, the first MAP decoder may include a first BM (Branch Matric) operation unit for BM operating the first data that is included in the first data block and includes encoded noise from the outside; a fifth storage unit for storing a result of performing BM operation from the first BM operation unit; a first BSM (Backward State Matric) operation unit for BSM operating based on a result of performing BM operation that is stored in the fifth storage unit; a sixth storage unit for storing a result of performing BSM operation from the first BSM operation unit; and a first FSM (Forward State Matric) & LLR (Log Likelihood Ratio) operation unit for performing FSM operation and performing LLR operation based on the result of performing BM operation that is stored in the fifth storage unit and the result of performing BSM operation that is stored in the sixth storage unit.

According to an aspect of the present invention, wherein the second MAP decoder may include a second BM operation unit for BM operating the interleaved data stored in the second storage unit and a data delayed by the third delay element; a seventh storage unit for storing a result of performing BM operation from the second BM operation unit; a second BSM operation unit for BSM operating based on a result of performing BM operation that is stored in the seventh storage unit; an eighth storage unit for storing a result of performing BSM operation from the second BSM operation unit; and a second FSM & LLR operation unit for performing FSM operation and performing LLR operation based on the result of performing BM operation that is stored in the seventh storage unit and the result of performing BSM operation that is stored in the eighth storage unit.

According to an aspect of the present invention, a control method of a turbo decoder for performing MAP decoding for a plurality of data blocks including encoded noise, includes performing, by a first MAP decoder, MAP decoding for a first data block that is included in the plurality of data blocks; interleaving, by an interleaver, a result of performing MAP decoding for the first data block; performing, by a second MAP decoder, MAP decoding based on a data included in the first data block and an interleaved data of the first data block; deinterleaving, by a deinterleaver, a result of performing MAP decoding from the second MAP decoder for the first data block; and storing the result of performing MAP decoding from the first MAP decoder, the interleaved data from the interleaver, the result of performing MAP decoding from the second MAP decoder and an deinterleaved data from the deinterleaver, by at least one storage unit that is formed between the first MAP decoder, the interleaver, the second MAP decoder and the deinterleaver.

According to an aspect of the present invention, the interleaving the result of performing MAP decoding for the first data block may include, when a first storage unit is formed between the first MAP decoder and the interleaver, interleaving the result of performing MAP decoding for the first data block that is stored in the first storage unit; and performing, by the first MAP decoder, MAP decoding for a second data block that is included in the plurality of data blocks.

According to an aspect of the present invention, the performing MAP decoding based on the data included in the first data block and the interleaved data of the first data block may include, when a second storage unit is formed between the interleaver and the second MAP decoder, performing, by the second MAP decoder, MAP decoding for the first data block that is stored in the second storage unit; and performing, by the first MAP decoder, MAP decoding for a second data block that is included in the plurality of data blocks or interleaving a result of performing MAP decoding for the second data block.

According to an aspect of the present invention, the deinterleaving the result of performing MAP decoding for the first data block may include, when a third storage unit is formed between the second MAP decoder and the deinterleaver, deinterleaving, by the deinterleaver, the first data block that is stored in the third storage unit; and performing by the first MAP decoder MAP decoding for a second data block that is included in the plurality of data blocks, interleaving by the interleaver a result of performing MAP decoding for the second data block, or performing by the second MAP decoder MAP decoding an interleaved data of the data block.

According to an embodiment of the present invention, a turbo decoder of half pipelined scheme and a method for controlling thereof may improve the throughput of decoding a plurality of data blocks by forming at least one storage unit between a first MAP decoder, an interleaver, a second MAP decoder and a deinterleaver, and performing operation function for each data block in half pipelined scheme.

According to an embodiment of the present invention, a turbo decoder of half pipelined scheme and a method for controlling thereof may be easily implemented without performance degradation by forming at least one storage unit between a BM operation unit, a BSM operation unit and a FSM/LLR operation unit, and performing operation function for each data block in half pipelined scheme, where the BM operation unit, the BSM operation unit and the FSM/LLR operation unit constitute a MAP decoder.

### BRIEF DESCRIPTION OF THE DRAWINGS

The above and other features and advantages of certain embodiments of the present invention will became more apparent from the following detailed description taken in conjunction with the accompanying drawings in which:

FIG. 1 is a block diagram of a turbo decoder of half pipelined scheme, according to an embodiment of the present invention.

FIG. 2 is a diagram illustrating an example of operation sequence of a turbo decoder, according to an embodiment of the present invention.

FIG. 3 is a block diagram of a first MAP decoder, according to an embodiment of the present invention.

FIG. 4 is a block diagram of a second MAP decoder, according to an embodiment of the present invention.

FIG. 5 is a diagram illustrating an example of operation sequence of a turbo decoder, according to an embodiment of the present invention.

FIG. 6 is a diagram illustrating an example of operation sequence of half pipelined scheme in a first MAP decoder and in a second MAP decoder, according to an embodiment of the present invention.

FIG. 7 is a diagram illustrating an example of operation sequence by the components corresponding to FIG. 1, according to an embodiment of the present invention.

FIG. 8 is a flowchart illustrating a control method of a turbo decoder, according to an embodiment of the present invention.

### DESCRIPTION OF EMBODIMENTS

The technical term as used herein is only used for the purpose of describing particular embodiments and is not intended to limit the present invention, it should be noted. In addition, the technical term used in the present invention should be interpreted as a meaning understood by one of ordinary skill in the art unless it is defined particularly as a different meaning in the present invention, and it should not be interpreted as an excessively broad meaning or an excessively narrow meaning. Further, if the technical term used in this invention is an incorrect technical term that does not accurately represent the spirit of the present invention, it should be understood to be replaced as a correct technical term able to be understood by one of ordinary skill in the art. Further, the general term used in the present invention should be interpreted according to a meaning of the dictionary or the context of the pre or post passages, it should not be interpreted as an excessively narrow meaning.

The expression of a singular used in the present invention includes the expression of a plurality thereof, unless it represents clearly a different meaning in the context. As used herein, the term “constituted by”, “include” or the like should not be interpreted as having to contain all of various components or various steps described in the invention necessarily, it should be interpreted as that a part of those components or steps may not be included or that additional components or steps may be further included.

Further, the terms that include the ordinal number such as the first, the second or so on, may used for describe the components, but the components should not be limited by the terms. The terms are used only for distinguishing one component from the other component. For example, without departing from the scope of the present invention, a first component may be named to a second component, and similarly the second component also may be named to the first component.

Hereinafter, with reference to the accompanying drawings, exemplary embodiment according to the present invention will be described in detail, but the same or similar components are given the same reference numeral and thus their redundant description will be omitted.

Further, in describing the present invention, if it is determined that a detailed description of a known technique may obscure the subject of the present invention, the detailed description may be omitted. Further, the attached drawings are to enable to easily understand the spirit of the present invention, but it should not be construed that the present invention is limited to the attached drawings, that should be noted.

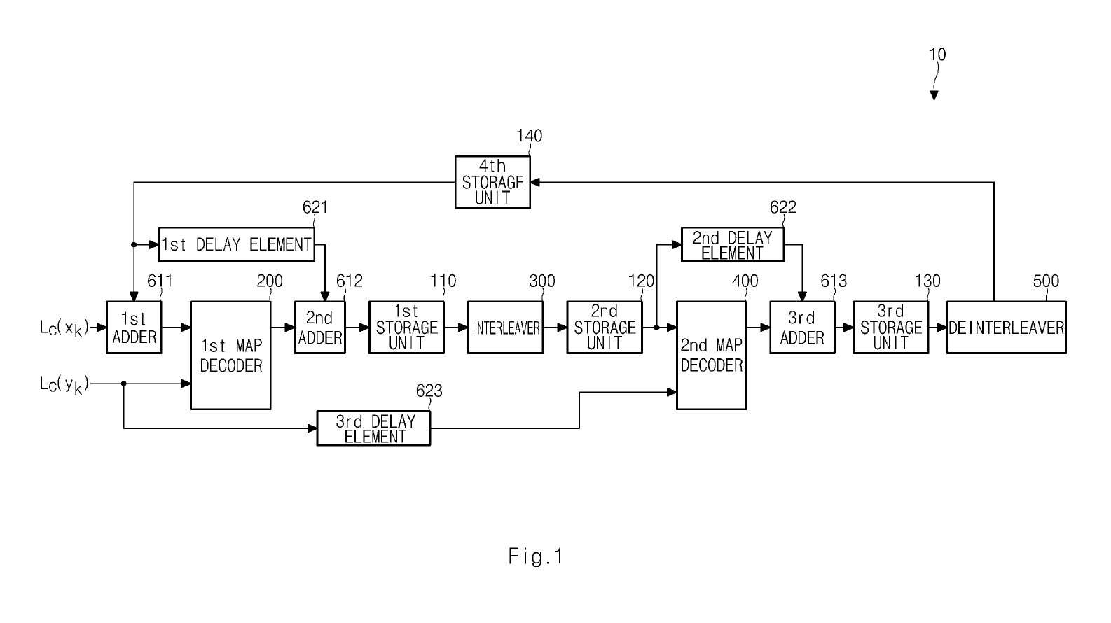

FIG. 1 is a block diagram of a turbo decoder of half pipelined scheme, according to an embodiment of the present invention.

As shown in FIG. 1, a turbo decoder 10 includes a storage unit 100, a first MAP decoder 200, an interleaver 300, a second MAP decoder 400, a deinterleaver 500, a first adder 611, a second adder 612, a third adder 613, a first delay element 621, a second delay element 622 and a third delay element 623. As shown in FIG. 1, all the components that are included in the turbo decoder 10 are not mandatory components, the turbo decoder 10 may be implemented with many components more than illustrated in FIG. 1, or the turbo decoder 10 may be implemented with fewer components than illustrated in FIG. 1.

The first MAP decoder 200, the interleaver 300, the second MAP decoder 400 and the deinterleaver 500 constitute the turbo decoder 10, at least one storage unit 100 is formed between the first MAP decoder 200, the interleaver 300, the second MAP decoder 400 and the deinterleaver 500, and operation function for the different data blocks among a plurality of data blocks is performed during a predetermined operation time (T) on a front and a rear of the at least one storage unit 100. Herein, the operation time (T) may be set variously according to the design of the architect considering the operation time of the first MAP decoder 200, the interleaver 300, the second MAP decoder 400 and the deinterleaver 500 which are included in the turbo decoder 10.

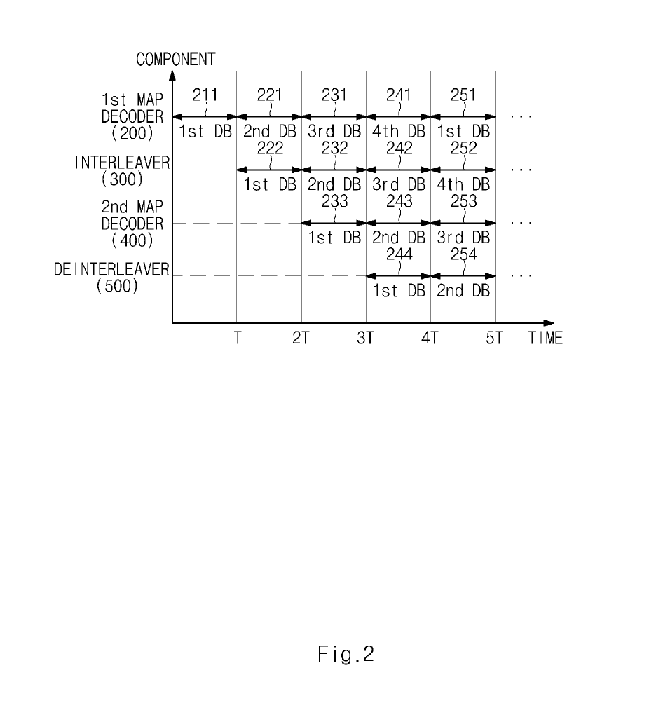

As shown in FIG. 1, in condition that a first storage unit 110, a second storage unit 120, a third storage unit 130 and a fourth storage unit 140 is formed respectively between the first MAP decoder 200, the interleaver 300, the second MAP decoder 400 and the deinterleaver 500, the order of operations for the data block may be as in FIG. 2.

As shown in FIG. 2, after the first MAP decoder 200 performs MAP decoding for a first data block at a first operation time (T), result of the performing MAP decoding for the first data block (or the first DB(data block)) is stored in the first storage unit 110 (211). Herein, the operation time (T) may be set as the longest time among a time of adding performing time of MAP decoding by the first MAP decoder 200 and storing time of the result of performing MAP decoding, a time of adding performing time of interleaving by the interleaver 300 and storing time of interleaved data, a time of adding performing time of MAP decoding by the second MAP decoder 400 and storing time of the result of performing MAP decoding, and a time of adding performing time of deinterleaving by the deinterleaver 500 and storing time of deinterleaved data.

Then, at a second operation time (2T), after the interleaver 300 interleaves based on result of performing MAP decoding for the first data block that is stored temporarily in the first storage unit 110, the interleaved data for the first data block is stored in the second storage unit 120 (222), and after performing MAP decoding for a second data block (or a second DB) by the first MAP decoder 200, the result of performing MAP decoding for the second data block is stored in the first storage unit 110 (221).

Then, at a third operation time (3T), after the second MAP decoder 400 performs MAP decoding based on interleaved data for the first data block that is stored temporarily in the second storage unit 120 and temporarily delayed data, the result of performing MAP decoding for the first data block by the second MAP decoder 400 is stored in the third storage unit 130 (233), after the interleaver 300 interleaves based on result of performing MAP decoding for the second data block that is stored temporarily in the first storage unit 110, the interleaved data for the second data block is stored in the second storage unit 120, and after the first MAP decoder 200 performs MAP decoding for a third data block (or a third DB), the result of performing MAP decoding for the third data block is stored in the first storage unit 110 (231).

Then, at a fourth operation time (4T), after the deinterleaver 500 deinterleaves based on result of performing MAP decoding by the second MAP decoder 400 for the first data block that is stored temporarily in the third storage unit 130, the deinterleaved data for the first data block is stored in the fourth storage unit 140 (244), after the second MAP decoder 400 performs MAP decoding based on interleaved data for the second data block that is stored temporarily in the second storage unit 120 and temporarily delayed data, the decoding result of MAP decoding by the second MAP decoder 400 for the second data block 400 is stored in the third storage unit 130 (243), and after the interleaver 300 interleaves based on result of performing MAP decoding by the first MAP decoder 200 for a fourth data block (or a fourth DB), the result of performing MAP decoding for the fourth data block is stored in the first storage unit 110 (241).

Then, at a fifth operation time (5T), the deinterleaver 500 performs operation function (e.g. deinterleaving function) for the second data block that is stored temporarily in the third storage unit 130 (254), the second MAP decoder 400 performs operation function (e.g. MAP decoding function) for the third data block that is stored temporarily in the second storage unit 120 (253), the interleaver 300 performs operation function (e.g. interleaving function) for the fourth data block that is stored temporarily in the first storage unit 110 (252), the first MAP decoder 200 performs operation function (e.g. MAP decoding function) respectively based on the first data block that is stored temporarily in the fourth storage unit 140 and a part of data of received first data block (251).

Thus, if the at least one storage unit 100 is included between the first MAP decoder 200, the second MAP decoder 400 and the deinterleaver 500 which are included in the turbo decoder 10, operation function may be performed concurrently for the number of data blocks corresponding to the number of the included storage unit 100.

At this time, the turbo decoder 10 performs 8 to 12 times the decoding process for a particular data block repeatedly.

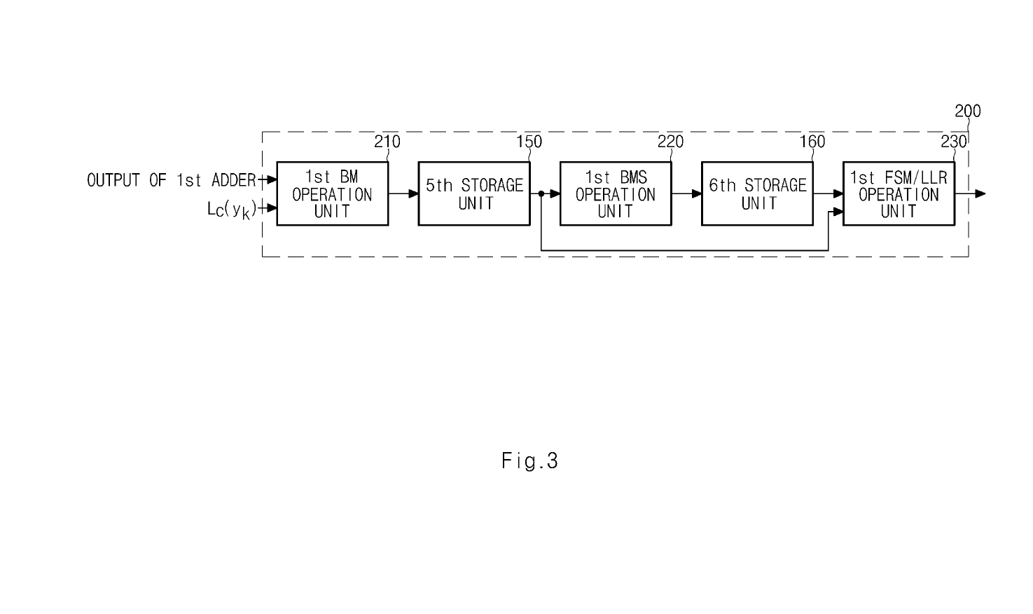

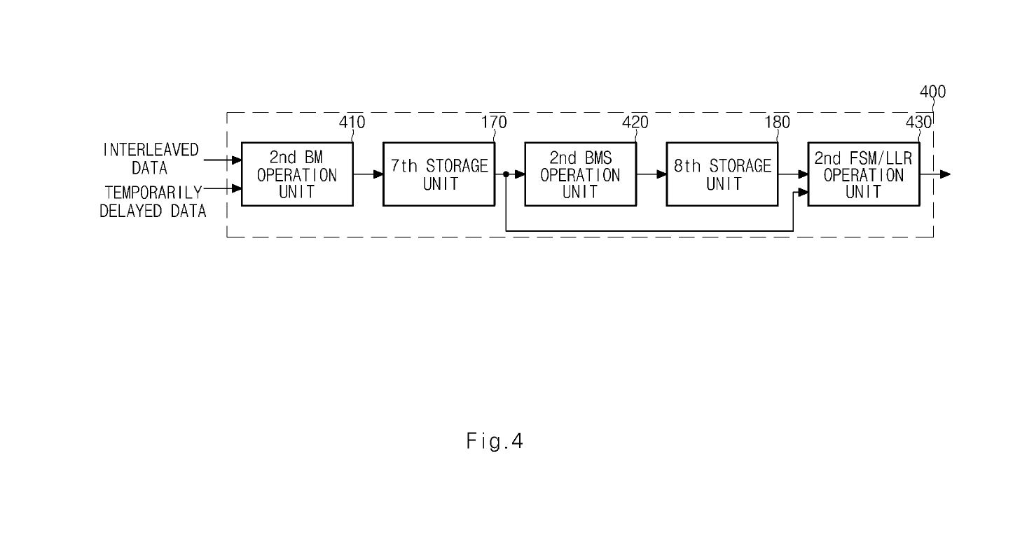

As shown in FIG. 1, FIG. 3 and FIG. 4, the storage unit 100 is composed of the first storage unit 110, the second storage unit 120, the third storage unit 130, the fourth storage unit 140, a fifth storage unit 150, a sixth storage unit 160, a seventh storage unit 170 and an eighth storage unit 180. Herein, the storage unit 100 may include storage medium such as RAM (Random Access Memory: RAM), SRAM (Static Random Access Memory), etc.

Further, as shown in FIG. 1, the first storage unit 110 is formed between the first MAP decoder 200 and the interleaver 300.

Further, the first storage unit 110 stores result of performing MAP decoding (or result of performing LLR operation) for a particular data block transmitted (or recoded) from the first MAP decoder 200.

In other words, the first storage unit 110 stores data transmitted from a second adder 612 (or result of performing MAP decoding for a particular data block) temporarily. Herein, the second adder 612 adds data that is temporarily delayed by a first delay element 621 and decoding result of MAP decoding for the data block by the first MAP decoder 200 (or LLR operation result of a first FSM & LLR operation unit 230 that is included in the first MAP decoder 200), and transmits the added data to the first storage unit 110 or the interleaver 300. At this time, the first delay element 621 delays deinterleaved data from the deinterleaver 500 or deinterleaved data from the deinterleaver 500 that is stored temporarily in the fourth storage unit 140, and outputs the delayed result according to an output order of the first MAP decoder 200.

Further, after recoding by the first storage unit 110 result of performing MAP decoding for a particular data block from the first MAP decoder 200 is completed, result of performing MAP decoding for the particular data block stored temporarily in the first storage unit 110 from the first MAP decoder 200 may be read by the interleaver 300.

Thus, the first storage unit 110 is located between the first MAP decoder 200 and the interleaver 300, stores temporarily result of performing MAP decoding output from the first MAP decoder 200 for the particular data block, and provides the result of performing MAP decoding stored temporarily for the particular data block to the interleaver 300.

Further, as shown in FIG. 1, the second storage unit 120 is formed between the interleaver 300 and the second MAP decoder 400.

Further, the second storage unit 120 stores interleaved data for the particular data block transmitted from the interleaver 300.

In other words, the second storage unit 120 stores the interleaved data performed by the interleaver 300 for the first data block temporarily.

Further, after recoding by the second storage unit 120 the interleaved data for the particular data block from the interleaver 300 is completed, the interleaved data performed by the interleaver 300 for the particular data block that is stored temporarily in the second storage unit 120 may be read by the second MAP decoder 400 or a second delay element 622.

Thus, the second storage unit 120 is located between the interleaver 300 and the second MAP decoder 400, stores the interleaved data output from the interleaver 300 for the particular data block, and provides the interleaved data for the particular data block stored temporarily to the second MAP decoder 400.

Further, as shown in FIG. 1, the third storage unit 130 is formed between the second MAP decoder 400 and the deinterleaver 500.

Further, the third storage unit 130 stores (or writes) result of performing MAP decoding (or result of performing LLR operation) for the particular data block transmitted (or written) from the second MAP decoder 400.

In other words, the third storage unit 130 stores data (or result of performing MAP decoding for the particular data block) transmitted from a third adder 613. Herein, the third adder 613 adds data that is temporarily delayed by the second delay element 622 and result of performing MAP decoding for the data block from the second MAP decoder 400 (or LLR operation result of a second FSM & LLR operation unit 430 included in the second MAP decoder 400), and transmits the added data to the third storage unit 130 or the deinterleaver 500. At this time, the second delay element 622 delays temporarily interleaved data from the interleaver 300 or interleaved data from the interleaver 300 that is stored temporarily in the second storage unit 120, and outputs the delayed result according to an output order of the second MAP decoder 400.

Further, after storing by the third storage unit 130 result of performing MAP decoding for the particular data block from the second MAP decoder 400 is completed, result of performing MAP decoding performed by the second MAP decoder 400 for the particular data block stored temporarily in the third storage unit 130 may be read by the deinterleaver 500.

Thus, the third storage unit 130 is located between the second MAP decoder 400 and the deinterleaver 500, stores temporarily result of performing MAP decoding for the particular data block output from the second MAP decoder 400, and provides the result of performing MAP decoding for the particular data block stored temporarily to the deinterleaver 500.

Further, as shown in FIG. 1, the fourth storage unit 140 is formed between the deinterleaver 500 and the first MAP decoder 200.

Further, the fourth storage unit 140 stores the deinterleaved data for the particular data block transmitted from the deinterleaver 500.

In other words, the fourth storage unit 140 stores the deinterleaved data performed by the deinterleaver 500 for the first data block temporarily.

Further, after recoding by the fourth storage unit 140 the deinterleaved data for the particular data block from the deinterleaver 500 is completed, the deinterleaved data performed by the deinterleaver 500 for the particular data block stored temporarily in the fourth storage unit 140 may be read by the first MAP decoder 200 or the first delay element 621.

Thus, the fourth storage unit 140 is located between the deinterleaver 500 and the first MAP decoder 200, stores the deinterleaved data output from the deinterleaver 500 for the particular data block, and provides the deinterleaved data for the particular data block stored temporarily to the first MAP decoder 200.

Further, as shown in FIG. 3 and FIG. 4, the fifth storage unit 150 and the seventh storage unit 170 are formed between a first BM operation unit 210 and a first BSM operation unit 220, between a second BM operation unit 410 and a second BSM operation unit 420, respectively.

Further, the fifth storage unit 150 and the seventh storage unit 170 store result of performing BM operation transmitted (or written) from the first BM operation unit 210 and the second BM operation unit 410 respectively.

Further, each of result of performing BM operation stored temporarily in the fifth storage unit 150 and the seventh storage unit 170 may be read by the first BSM operation unit 220 and the first FSM & LLR operation unit 230, the second BSM operation unit 420 and the second FSM & LLR operation unit 430, respectively.

Further, as shown in FIG. 3 and FIG. 4, the sixth storage unit 160 and the eighth storage unit 180 are formed between a first BSM operation unit 220 and a first FSM & LLR operation unit 230, between a second BSM operation unit 420 and a second FSM & LLR operation unit 430, respectively.

Further, the sixth storage unit 160 and the eighth storage unit 180 store temporarily result of performing BSM operation transmitted (or written) from the first BSM operation unit 220 and the second BSM operation unit 420 respectively.

Further, each of result of performing BSM operation stored temporarily in the sixth storage unit 160 and the eighth storage unit 180 may be read by the first FSM & LLR operation unit 230 and the second FSM & LLR operation unit 430, respectively.

Thus, the at least one (or plurality of) storage unit 100 may be formed between the components included in the turbo decoder 10 (e.g. the first MAP decoder 200, the interleaver 300, the second MAP decoder 400 and the deinterleaver 500) or the components included in the first MAP decoder 200/the second MAP decoder 400 (e.g. the first BM operation unit 210, the first BSM operation unit 220, the first FSM & LLR operation unit 230, the second BM operation unit 410, the second BSM operation unit 420 and the second FSM & LLR operation unit 430).

Further, size of the storage unit 100 (or memory) included in the turbo decoder 10 may be like the below.

In other words, if the storage unit 100 included in the turbo decoder 10 includes all of the first storage unit to the eighth storage unit (110, 120, 130, 140, 150, 160, 170 and 180), the total size of the storage unit 100 may be same to 14 (size of data block).

In case of an internal memory of the MAP decoder (e.g. the first MAP decoder 200 or the second MAP decoder 400), BM operation value of the first data block has to be maintained by the time that is FSM and LLR operated (or BM operation value of the first data block also has to be maintained by the time when the BM operation value of the third data block is stored). Therefore, the memory size of the MAP decoder has to be at least 3 (size of data block).

Further, in case of the total structure of the turbo decoder 10, the place of the greatest use of the memory is the interleaver 300 and the deinterleaver 500, the second data block has to be input when being interleaved is output after all of the first data block is stored. Therefore, in case of the total structure of the turbo decoder 10, size of each memory has to be at least 2 (size of data block).

Further, size of the memory of the first to the fourth storage unit (110, 120, 130, 140) is 8 (size of data block), and size of the first and the second MAP decoder (200, 400) internal (the fifth storage unit 150, the sixth storage unit 160, the seventh storage unit 170 and the eighth storage unit 180) memory is 6 (size of data block).

Therefore, total size of the total storage unit (or memory) has to be set to maintain at least 14 (size of data block).

Thus, total size of the total storage unit 100 may be set variously according to the number of storage unit included in the turbo decoder 10.

Further, if a storage unit 100 is formed, the operations for data blocks which are different each other may be performed concurrently on a front and a rear where the relevant storage unit 100 is formed during the predetermined operation time (T).

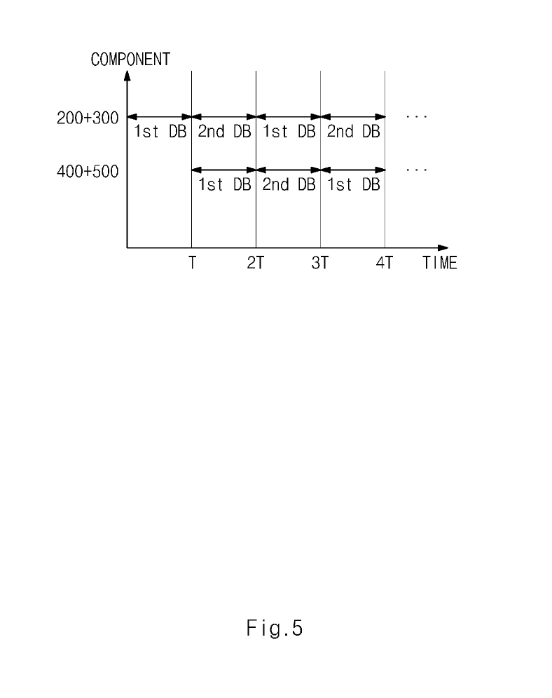

For example, if the second storage unit 120 is formed only between the interleaver 300 and the second MAP decoder 400, as shown in FIG. 5, MAP decoding by the first MAP decoder 200 for one data block among the plurality of data blocks during the first operation time (T) is performed, after interleaving by the interleaver 300 based on the result of performing MAP decoding for the one data block, the interleaved data for the one data block is stored in the second storage unit 120.

After that, at the second operation time (2T), MAP decoding based on the interleaved data for the one data block that is stored temporarily in the second storage unit 120 and temporarily delayed data is performed by the second MAP decoder 400, after the deinterleaver 500 deinterleaves based on result of performing MAP decoding for the one data block from the second MAP decoder 400, the deinterleaved data for the first data block is transmitted to the first MAP decoder 200. Further, at the second operation time (2T), MAP decoding by the first MAP decoder 200 for different data block among the plurality data blocks is performed, after interleaving by the interleaver 300 based on the result of performing MAP decoding for the different data block, the interleaved data for the different data block is stored in the second storage unit 120.

After that, at the third operation time (3T), MAP decoding for the different data block that is stored temporarily in the second storage unit 120 is performed by the second MAP decoder 400, deinterleaving function for the result of performing MAP decoding from the second MAP decoder 400 is performed by the deinterleaver 500, MAP decoding function for the deinterleaved data of one data block is performed by the first MAP decoder 200, and after interleaving function for the result of performing MAP decoding from the first MAP decoder 200 is performed by the interleaver 300, the interleaved data for the one data block is stored in the second storage unit 120.

Thus, if at least one storage unit 100 is formed between the first MAP decoder 200, the interleaver 300, the second MAP decoder 400 and the deinterleaver 500 included in the turbo decoder 10, operation for data blocks which are different each other may be performed on a front and a rear of where the storage unit 100 is formed.

The first MAP (Maximum A Posteriori) decoder 200 performs MAP decoding for received (or input) data block, transmits (or writes/stores) the result of performing MAP decoding to the first storage unit 110 or the second adder 612.

As shown in FIG. 3, the first MAP decoder 200 is comprised of the first BM operation unit 210, the fifth storage unit 150, the first BSM operation unit 220, the sixth storage unit 160 and the first FSM & LLR operation unit 230. As shown in FIG. 3, all the components that are included in the first MAP decoder 200 are not mandatory components, the first MAP decoder 200 may be implemented with many components more than illustrated in FIG. 3, or the first MAP decoder 200 may be implemented with fewer components than illustrated in FIG. 3. Herein, the first MAP decoder 200 may include at least one of the fifth storage unit 150 and the sixth storage unit 160.

The first BM (Branch Matric) operation unit 210 receives a particular data block (e.g. the first data block) that includes a second data (e.g. L_{c}(yₖ) as shown in FIG. 1) including output data from the first adder 611 and encoded noise from an outside. Herein, the first adder 611 adds a first data that includes the encoded noise from the outside and deinterleaved data that is stored temporarily in the fourth storage unit 140 from the deinterleaver 500, transmits the added data to the first MAP decoder 200 (or the first BM operation unit 210 included in the first MAP decoder 200).

Further, the first BM operation unit 210 performs BM operation (or branch operation) for the received particular data block, transmits (or writes/stores) the result of performing BM operation to the fifth storage unit 150 if the fifth storage unit 150 is formed, and transmits the result of performing BM operation to the first BSM operation unit 220 if the fifth storage unit 150 is not formed.

Further, if BM operation of the first BM operation unit 210 for the particular data block is completed, BM operation for a new different data block (e.g. the second data block) is performed.

Thus, the fifth storage unit 150 may be formed between the first BM operation unit 210 and the first BSM operation unit 220, and stores temporarily the result of performing BM operation transmitted (or written) from the first BM operation unit 210.

Further, the result of performing BM operation that is stored in the fifth storage unit 150 may be read by the first BSM operation unit 220 and the first FSM & LLR operation unit 230 respectively.

The first BSM (Backward State Matric) operation unit 220 performs BSM operation (or Backward State Matric operation) based on result of performing BM operation transmitted from the first BM operation unit 210 or result of performing BM operation that is stored temporarily in the fifth storage unit 150. At this time, when BSM operation for the particular data block (e.g. the first data block) is performed by the first BSM operation unit 220, BM operation for the new different data block (e.g. the second data block) is performed by the first BM operation unit 210, the relevant result of performing BM operation is stored in the fifth storage unit 150.

Further, the first BSM operation unit 220 transmits the result of performing BSM operation to the sixth storage unit 160 if the sixth storage unit 160 is formed, transmits the result of performing BSM operation to the first FSM & LLR operation unit 230 if the sixth storage unit 160 is not formed.

Thus, the sixth storage unit 160 may be formed between the first BSM operation unit 220 and the first FSM & LLR operation unit 230, and stores temporarily the result of performing BSM operation transmitted from the first BSM operation unit 220.

Further, the result of performing BSM operation that is stored in the sixth storage unit 160 may be read by the first FSM & LLR operation unit 230.

The first FSM & LLR (Forward State Matric & Log Likelihood Ratio) operation unit 230 performs FSM operation and LLR operation based on the result of performing BSM operation transmitted from the first BSM operation unit 220 and the result of performing BM operation stored temporarily in the fifth storage unit 150.

Further, The first FSM & LLR operation unit 230 performs FSM operation and LLR operation based on the result of performing BSM operation stored temporarily in the sixth storage unit 160 and the result of performing BM operation stored temporarily in the fifth storage unit 150.

In other words, the first FSM & LLR operation unit 230 performs FSM operation (or Forward State Matric operation) based on the result of performing BM operation stored temporarily in the fifth storage unit 150. After that, the first FSM & LLR operation unit 230 performs LLR operation (or Log Likelihood Ratio operation) based on result of performing BM operation, result of performing BSM operation and result of performing FSM operation.

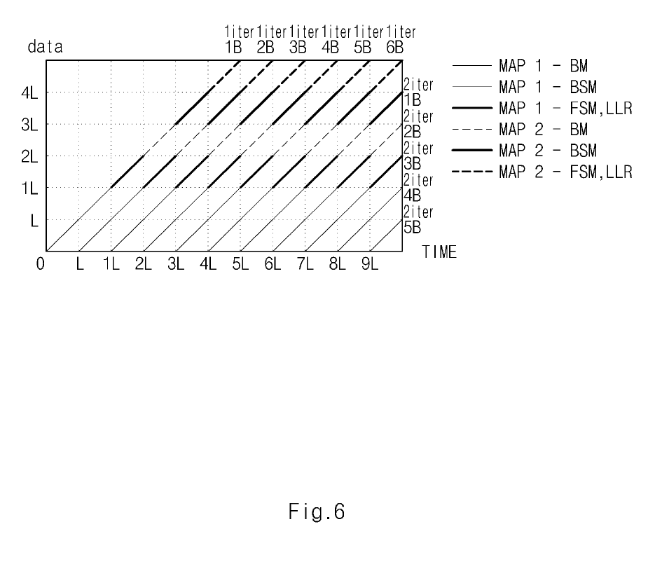

Further, when FSM and LLR operation for particular data block is performed by the first FSM & LLR operation unit 230, operation order of the first BM operation unit 210 and the first BSM operation unit 220 is as the illustrated in FIG. 6. In other words, when FSM and LLR operation for the first data block is performed by the first FSM & LLR operation unit 230, BM operation for new different data block is performed by the first BM operation unit 210 and the result of performing BM operation is stored in the fifth storage unit 150, BSM operation for the second data block which is the new different data block is performed by the first BSM operation unit 220 and the result of performing BSM operation is stored in the sixth storage unit 160.

Thus, in embodiments of the present invention, performing operations at once for the plurality of data blocks according to pipelined scheme may be called half pipelined scheme (or half pipelined decoding scheme).

Further, the first FSM & LLR operation unit 230 transmits the LLR operation result (or the result of performing MAP decoding for the data block) to the first storage unit 110 or the interleaver 300.

After performing of MAP decoding by the first MAP decoder 200 for the particular data block (e.g. the first data block) is completed, the interleaver 300 interleaves based on the result of performing MAP decoding for the particular data block stored temporarily in the first storage unit 110.

In other words, the interleaver 300 interleaves the result of performing MAP decoding (or result of performing LLR operation) for the first data block stored temporarily in the first storage unit 110. At this time, when interleaving for the first data block is performed by the interleaver 300, MAP decoding for the second data block which is new different data block may be performed by the first MAP decoder 200.

Further, if the storage unit (e.g. the first storage unit 110) is not formed between the first MAP decoder 200 and the interleaver 300, the interleaver 300 interleaves the result of performing MAP decoding for the particular data block from the first MAP decoder 200.

Further, the interleaver 300 transmits the interleaved data to the second storage unit 120, the second delay element 622 or the second MAP decoder 400.

The second MAP decoder 400 performs MAP decoding for the is received data block, and transmits the result of performing MAP decoding to the third storage unit 130 or the third adder 613.

As shown in FIG. 4, the second MAP decoder 400 is comprised of the second BM operation unit 410, the seventh storage unit 170, the second BSM operation unit 420, the eighth storage unit 180 and the second FSM & LLR operation unit 430. As shown in FIG. 4, all the components that are included in the second MAP decoder 400 are not mandatory components, the second MAP decoder 400 may be implemented with many components more than illustrated in FIG. 4, or the second MAP decoder 400 may be implemented with fewer components than illustrated in FIG. 4. Herein, the second MAP decoder 400 may include at least one of the seventh storage unit 170 and the eighth storage unit 180.

The second BM operation unit 410 performs BS operation for data output from the interleaver 300 (or interleaved data that is stored temporarily in the second storage unit 120) and for data that is delayed temporarily by the third delay element 623, transmits the result of performing BM operation to the seventh storage unit 170 if the seventh storage unit 170 is formed, and transmits the result of performing BM operation to the second BSM operation unit 420 if the seventh storage unit 170 is not formed. Herein, the third delay element 623 delays temporarily the second data that includes encoded noise from the outside and is included in the relevant particular data block, and outputs the delayed data according to output order of the interleaver 300 or reading order of the second storage unit 120.

Further, if BM operation for the particular data block is completed, the second BM operation unit 410 performs BM operation for new different data block (e.g. the second data block) output from the interleaver 300 or the interleaved data stored temporarily in the second storage unit 120.

Thus, the seventh storage unit 170 may be formed between the second BM operation unit 410 and the second BSM operation unit 420, and stores temporarily the result of performing BM operation transmitted (or written) from the second BM operation unit 410.

Further, the result of performing BM operation stored temporarily in the seventh storage unit 170 may be read by the second BSM operation unit 420 and the second FSM & LLR operation unit 430 respectively.

The second BSM operation unit 420 performs BSM operation (or Backward State Matric operation) based on the result of performing BS operation transmitted from the second BM operation unit 410 or the result of performing BM operation stored temporarily in the seventh storage unit 170. At this time, when BSM operation for the particular data block (e.g. the first data block) is performed by the second BSM operation unit 420, BM operation for new different data block (e.g. the second data block) is performed by the second BM operation unit 410, and the relevant result of performing BM operation is stored in the seventh storage unit 170.

Further, the second BSM operation unit 420 transmits the result of performing BSM operation to the eighth storage unit 180 if the eighth storage unit 180 is formed, transmits the result of performing BSM operation to the second FSM & LLR operation unit 430 if the eighth storage unit 180 is not formed.

Thus, the eighth storage unit 180 may be formed between the second BSM operation unit 420 and the second FSM & LLR operation unit 430, and stores the result of performing BSM operation transmitted (or written) from the second BSM operation unit 420.

Further, the result of performing BSM operation stored temporarily in the eighth storage unit 180 may be read by the second FSM & LLR operation unit 430.

The second FSM & LLR operation unit 430 performs FSM operation and LLR operation based on the result of performing BSM operation transmitted from the second BSM operation unit 420 and the result of performing BM operation stored temporarily in the seventh storage unit 170.

Further, The second FSM & LLR operation unit 430 performs FSM operation and LLR operation based on the result of performing BSM operation stored temporarily in the eighth storage unit 180 and the result of performing BM operation stored temporarily in the seventh storage unit 170.

In other words, the second FSM & LLR operation unit 430 performs FSM operation (or Forward State Matric operation) based on the result of performing BM operation stored temporarily in the seventh storage unit 170. After that, the second FSM & LLR operation unit 430 performs LLR operation based on the result of performing BM operation, the result of performing BSM operation and the result of performing FSM operation.

Further, the second FSM & LLR operation unit 430 transmits the LLR operation result (or the result of performing MAP decoding for the data block) to the third storage unit 130 or the deinterleaver 500 through a third adder 613.

After performing of MAP decoding by the second MAP decoder 400 for the particular data block (e.g. the first data block) is completed, the deinterleaver 500 deinterleaves based on the result of performing MAP decoding for the particular data block stored temporarily in the third storage unit 130.

In other words, the deinterleaver 500 deinterleaves the result of performing MAP decoding (or the result of performing LLR operation) for the first data block stored temporarily in the third storage unit 130. At this time, when deinterleaving for the first data block is performed by the deinterleaver 500, MAP decoding for a new fourth data block is performed by the first MAP decoder 200, interleaving for a third data block is performed by the interleaver 300, and MAP decoding for the second data block is performed by the second MAP decoder 400.

Further, if the storage unit (e.g. the third storage unit 130) is not formed between the second MAP decoder 400 and the deinterleaver 500, the deinterleaver 500 deinterleaves the result of performing MAP decoding for the particular data block from the second MAP decoder 400.

Further, the deinterleaver 500 transmits the deinterleaved data to the fourth storage unit 140, the first adder 611 or the first delay element 621. At this time, the interleaved data which is transmitted to the fourth storage unit 140, the first adder 611 or the first delay element 621 is transmitted (or feedbacked) as an input of the first MAP decoder 200, and function eliminating noise that is included in the signal (or data) transmitted from the first MAP decoder 200 is performed.

The first adder 611 adds the first data (e.g. L_{c}(xₖ) as shown in FIG. 1) including encoded noise from the outside and the deinterleaved data of the deinterleaver 500 (or the deinterleaved data of the deinterleaver 500 stored temporarily in the fourth storage unit 140), transmits the added data to the first MAP decoder 200 (or the first BM operation unit 210 included in the first MAP decoder 200).

The second adder 612 adds the data that is temporarily delayed by the first delay element 621 and the result of performing MAP decoding for the data block from the first MAP decoder 200 (or LLR operation result of the first FSM & LLR operation unit 230 included in the first MAP decoder 200), and transmits the added data to the first storage unit 110 or the interleaver 300.

The third adder 613 adds the data that is temporarily delayed by the second delay element 622 and the result of performing MAP decoding for the data block from the second MAP decoder 400 (or LLR operation result of the second FSM & LLR operation unit 430 included in the second MAP decoder 400), and transmits the added data to the third storage unit 130 or the deinterleaver 500.

The first delay element 621 delays temporarily the data that is deinterleaved by the deinterleaver 500 or the data that is deinterleaved by the deinterleaver 500 stored temporarily in the fourth storage unit 140, and outputs the delayed data according to the output order of the first MAP decoder 200.

The second delay element 622 delays temporarily the data that is interleaved by the interleaver 300 or the data that is interleaved by the interleaver 300 stored temporarily in the second storage unit 120, and outputs the delayed data according to the output order of the second MAP decoder 400.

The third delay element 623 delays temporarily the second data that includes encoded noise from the outside, and outputs the delayed data according to the output order of the interleaver 300 or the reading order of the second storage unit 120.

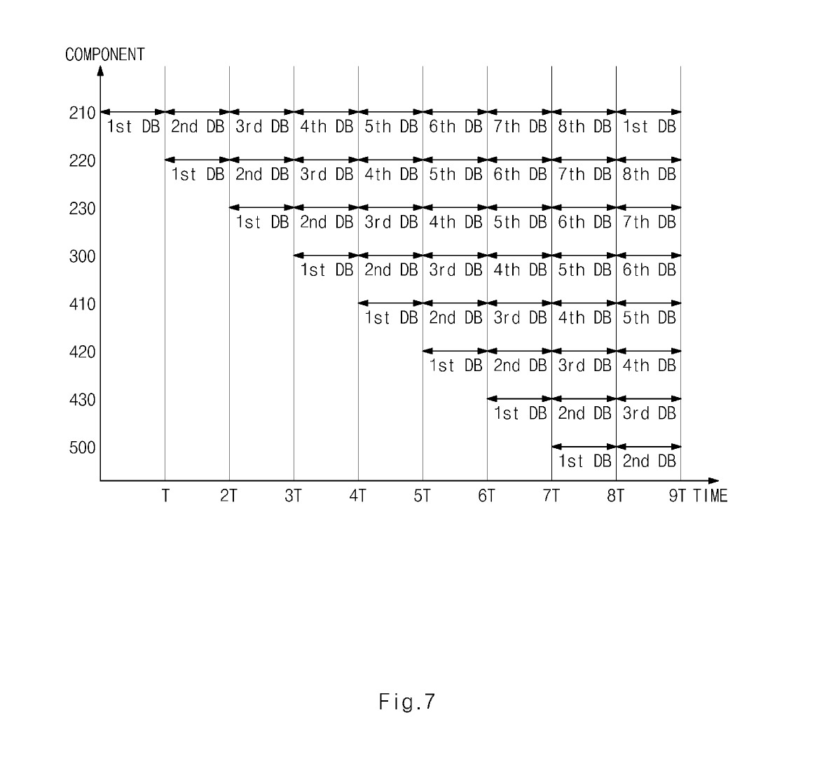

When the first to the eight storage unit (110, 120, 130, 140, 150, 160, 170 and 180) is included in the turbo decoder 10, FIG. 7 may represent operation order for the particular data block of the first BM operation unit 210, the first BSM operation unit 220, the first FSM & LLR operation unit 230, the interleaver 300, the second BM operation unit 410, the second BSM operation unit 420, the second FSM & LLR operation unit 430 and the deinterleaver 500.

As shown in FIG. 7, at the first operation time (T), BM operation for the first data block is performed by the first BM operation unit 210 included in the first MAP decoder 200.

After that, at the second operation time (2T), BSM operation for the first data block is performed by the first BSM operation unit 220, and BM operation for the second data block is performed by the first BM operation unit 210.

After that, at the third operation time (3T), FSM and LLR operation for the first data block is performed by the first FSM & LLR operation unit 230, BSM operation for the second data block is performed by the first BSM operation unit 220, and BM operation for the third data block is performed by the first BM operation unit 210.

After that, at the fourth operation time (4T), interleaving for the first data block is performed by the interleaver 300, FSM & LLR operation for the second data block is performed by the first FSM & LLR operation unit 230, BSM operation for the third data block is performed by the first BSM operation unit 220, and BM operation for the fourth data block is performed by the first BM operation unit 210.

After that, at the fifth operation time (5T), BM operation for the first data block is performed by the second BM operation unit 410 included in the second MAP decoder 400, interleaving for the second data block is performed by the interleaver 300, FSM and LLR operation for the third data block is performed by the first FSM & LLR operation unit 230, BSM operation for the fourth data block is performed by the first BSM operation unit 220, and BM operation for the fifth data block is performed by the first BM operation unit 210.

After that, at the sixth operation time (6T), BSM operation for the first data block is performed by the second BSM operation unit 420, BM operation for the second data block is performed by the second BM operation unit 410 included in the second MAP decoder 400, interleaving for the third data block is performed by the interleaver 300, FSM and LLR operation for the fourth data block is performed by the first FSM & LLR operation unit 230, BSM operation for the fifth data block is performed by the first BSM operation unit 220, and BM operation for the sixth data block is performed by the first BM operation unit 210.

After that, at the seventh operation time (7T), FSM & LLR operation for the first data block is performed by the second FSM & LLR operation unit 430, BSM operation for the second data block is performed by the second BSM operation unit 420, BM operation for the third data block is performed by the second BM operation unit 410 included in the second MAP decoder 400, interleaving for the fourth data block is performed by the interleaver 300, FSM and LLR operation for the fifth data block is performed by the first FSM & LLR operation unit 230, BSM operation for the sixth data block is performed by the first BSM operation unit 220, and BM operation for the seventh data block is performed by the first BM operation unit 210.

After that, at the eighth operation time (8T), deinterleaving for the first data block is performed by the deinterleaver 500, FSM & LLR operation for the second data block is performed by the second FSM & LLR operation unit 430, BSM operation for the third data block is performed by the second BSM operation unit 420, BM operation for the fourth data block is performed by the second BM operation unit 410 included in the second MAP decoder 400, interleaving for the fifth data block is performed by the interleaver 300, FSM and LLR operation for the sixth data block is performed by the first FSM & LLR operation unit 230, BSM operation for the seventh data block is performed by the first BSM operation unit 220, and BM operation for the eighth data block is performed by the first BM operation unit 210.

After that, after the process of total decoding for the first data block is completed once, at the ninth operation time (9T), the first data block is input to the first BM operation unit 210 again and the decoding process is performed repeatedly as a predetermined number of times (e.g. 8˜12 times).

Thus, the first MAP decoder 200, the interleaver 300, the second MAP decoder 400 and the deinterleaver 500 perform the relevant unique functions respectively without idle state based on each of the operation results of each of the components which are stored in the fourth storage unit 140, the first storage unit 110, the second storage unit 120 and the third storage unit 130.

Further, the first MAP decoder 200, the interleaver 300, the second MAP decoder 400 and the deinterleaver 500 may perform the decoding process for the particular data block repeatedly about 8˜12 times.

Thus, at least one storage unit may be formed between the first MAP decoder, the interleaver, the second MAP decoder and the deinterleaver, and operation function for each of data blocks is performed as pipelined scheme.

Further, thus, the at least one storage unit may be formed between the BM operation unit, BSM operation unit and FSM & LLR operation unit which constitute the MAP decoder, and operation function for each of data blocks is performed as pipelined scheme.

For the below, as shown in FIG. 1 to FIG. 8, control method of the turbo decoder in half pipelined scheme according to an embodiment of the present invention is described in detail.

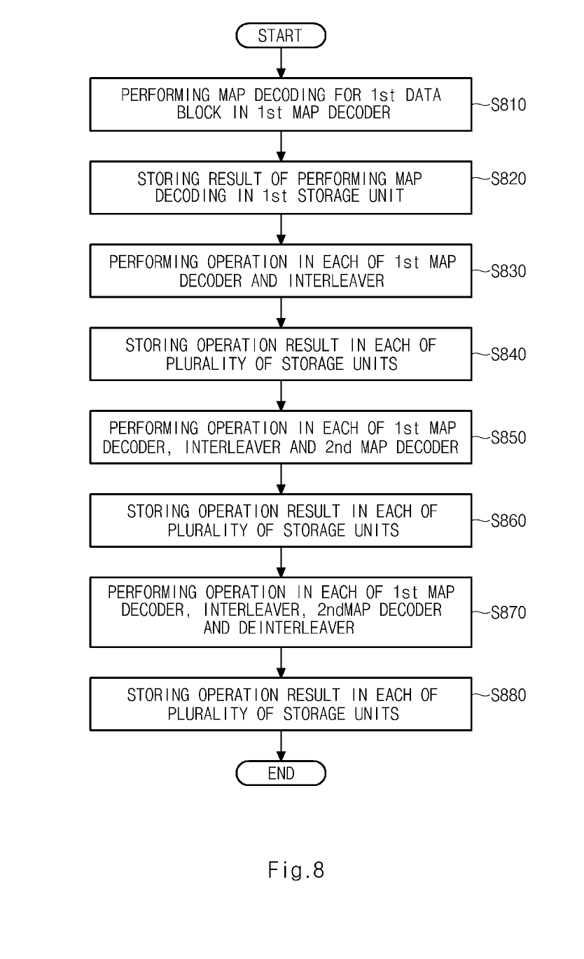

FIG. 8 is a flowchart illustrating the control method of the turbo decoder, according to an embodiment of the present invention.

At first, the first MAP decoder 200 performs MAP decoding based on the first data block. Herein, the first data block (or a first information signal) includes the data from adding the first data (or a first information) that includes encoded noise from the outside and the deinterleaved data of the deinterleaver 500 stored temporarily in the fourth storage unit 140, and the second data that includes encoded noise from the outside.

For example, as shown in FIG. 2, the first MAP decoder 200 performs BM operation for the first data block, performs BSM operation for the result of performing BM operation, after FSM operation based on the is result of performing BM operation is performed, performs LLR operation based on the result of performing BM operation, the result of performing BSM operation and the result of performing FSM operation (211) (S810).

After that, the first MAP decoder 200 transmits (or writes/stores) the result of performing MAP decoding for the first data block (or the result of performing LLR operation) to the first storage unit 110.

For example, the first MAP decoder 200 writes the result of performing LLR operation for the first data block to the first storage unit 110 (S820).

After that, if transmitting the result of performing MAP decoding for the first data block from the first MAP decoder 200 to the first storage unit 110 is completed (or MAP decoding of the first MAP decoder 200 for the first data block is completed), the first MAP decoder 200 performs MAP decoding for the second data block that is a new data block. Further, the interleaver 300 performs interleaving based on the result of performing MAP decoding for the first data block stored temporarily (or written temporarily) in the first storage unit 110.

For example, when writing the result of performing LLR operation from the first MAP decoder 200 to the first storage unit 110 is completed, as shown in FIG. 2, the first MAP decoder 200 performs MAP decoding for the second data block (221), the interleaver 300 interleaves the result of performing LLR operation for the first data block stored temporarily in the first storage unit 110 (S830).

After that, the first MAP decoder 200 transmits the result of performing MAP decoding for the second data block to the first storage unit 110. Further, the interleaver 300 transmits the interleaved data for the first data block (or the interleaved data as the result of performing interleaving of MAP decoding result for the first data block) to the second storage unit 120.

For example, the first MAP decoder 200 writes the result of performing LLR operation for the second data block, and the interleaver 300 writes the interleaved data for the first data block (or the interleaved data of the first data block) to the second storage unit 120 (S840).

After that, if transmitting the result of performing MAP decoding for the second data block from the first MAP decoder 200 to the first storage unit 110 is completed (or MAP decoding of the first MAP decoder 200 for the second data block is completed) and/or if transmitting the interleaved data for the first data block from the interleaver 300 to the second storage unit 120 is completed (or interleaving of the interleaver 300 for the first data block is completed), the first MAP decoder 200 performs MAP decoding for the third data block that is a new different data block. Further, the interleaver 300 performs interleaving based on the result of performing MAP decoding for the second data block stored temporarily in the first storage unit 110. Further, the second MAP decoder 400 performs MAP decoding based on the interleaved data for the first data block stored temporarily in the second storage unit 120 and the second data that includes encoded noise from the outside included in the first data block.

For example, when writing the result of performing LLR operation for the second data block from the first MAP decoder 200 to the first storage unit 110 is completed and writing the interleaved data for the first data block from the interleaver 300 to the second storage unit 120 is completed, as shown in FIG. 2, the first MAP decoder 200 performs MAP decoding for the third data block (231), the interleaver 300 interleaves the result of performing LLR operation for the second data block stored temporarily in the first storage unit 110 (232), the second MAP decoder 400 performs MAP decoding for the interleaved data of the first data block stored temporarily in the second storage unit 120 and the second data that includes encoded noise of the first data block (233) (S850).

After that, the first MAP decoder 200 transmits the result of performing MAP decoding for the third data block to the first storage unit 110. Further, the interleaver 300 transmits the interleaved data for the second data block (or the interleaved data as the result of performing interleaving the MAP decoding result for the second data block) to the second storage unit 120. Further, the second MAP decoder 400 transmits the result of performing MAP decoding for the first data block (or the result of performing LLR operation) to the third storage unit 130.

For example, the first MAP decoder 200 writes the result of performing LLR operation for the third data block to the first storage unit 110, the interleaver 300 writes the interleaved data for the second data block to the second storage unit 120, the second MAP decoder 400 writes the result of performing LLR operation for the first data block to the third storage unit 130 (S860).

After that, at least one of the case that transmitting the result of performing MAP decoding for the third data block from the first MAP decoder 200 to the first storage unit 110 is completed (or the case that MAP decoding of the first MAP decoder 200 for the third data block is completed), the case that transmitting the interleaved data from the interleaver 300 to the second storage unit 120 is completed (or the case that interleaving of the interleaver 300 for the second data block is completed) and the case that transmitting the result of performing MAP decoding for the first data block from the second MAP decoder 400 to the third storage unit 130 is completed (or the case that MAP decoding of the second MAP decoder 400 for the first data block is completed) is fulfilled (or met), the first MAP decoder 200 performs MAP decoding for the fourth data block that is another new different data block. Further, the interleaver 300 performs interleaving based on the result of performing MAP decoding for the third data block stored temporarily in the first storage unit 110. Further, the second MAP decoder 400 performs MAP decoding based on the interleaved data for the second data block stored temporarily in the second storage unit 120 and the second data that includes encoded noise from the outside included in the second data block. Further, the deinterleaver 500 performs deinterleaving based on the result of performing MAP decoding for the first data block stored temporarily in the third storage unit 130.

For example, when writing the result of performing LLR operation for the third data block from the first MAP decoder 200 to the first storage unit 110 is completed, writing the interleaved data for the second data block from the interleaver 300 to the second storage unit 120 is completed and writing the result of performing LLR operation for the first data block from the second MAP decoder 400 to the third storage unit 130 is completed, as shown in FIG. 2, the first MAP decoder 200 performs MAP decoding for the fourth data block (241), the interleaver 300 interleaves the result of performing LLR operation for the third data block stored temporarily in the first storage unit 110 (242), the second MAP decoder 400 performs MAP decoding for the interleaved data of the second data block stored temporarily in the second storage unit 120 and the second data that includes encoded noise of the second data block (243), the deinterleaver 500 performs deinterleaving for the first data block stored temporarily in the third storage unit 130 (244) (S870).

After that, the first MAP decoder 200 transmits the result of performing MAP decoding for the fourth data block (or the result of performing LLR operation) to the first storage unit 110. Further, the interleaver 300 transmits the interleaved data for the third data block to the second storage unit 120. Further, the second MAP decoder 400 transmits the result of performing MAP decoding (or the result of performing LLR operation) to the third storage unit 130. Further, the deinterleaver 500 transmits the deinterleaved data for the first data block to the fourth storage unit 140.

For example, the first MAP decoder 200 writes the result of performing LLR operation for the fourth data block to the first storage unit 110, the interleaver 300 writes the interleaved data for the third data block to the second storage unit 120, the second MAP decoder 400 writes the result of performing LLR operation for the second data block to the third storage unit 130, and the deinterleaver 500 writes the deinterleaved data for the first data block to the fourth storage unit 140 (S880).

Thus, the first MAP decoder 200, the interleaver 300, the second MAP decoder 400 and the deinterleaver 500 may perform each of the operation process repeatedly for the plurality of data blocks (e.g. the first to the fourth data block) as the predetermined number of times.

Further, if the decoding process repeated as the predetermined number of times for the first data block is completed, operation process is performed repeatedly for the other data block (the second to the fourth data block) except for the first data block among the prior plurality of data blocks (e.g. the first to the fourth data block) and for new fifth data block by the first MAP decoder 200, the interleaver 300, the second MAP decoder 400 and the deinterleaver 500.

Further, after MAP decoding by the first MAP decoder 200 for particular data block is completed, if transmitting the result of performing MAP decoding for the particular data block to the first storage unit 110 is completed, the first MAP decoder 200 may promptly perform MAP decoding for different particular data block regardless of whether the operation process of the interleaver 300, the second MAP decoder 400 or the deinterleaver 500 is completed or not.

In other words, regardless of that writing the result of performing MAP decoding from the first MAP decoder 200 to the first storage unit 110 is completed and interleaving of the interleaver 300 for the second data block is being performed, after writing the result of performing MAP decoding for the third data block to the first storage unit 110 is completed, the first MAP decoder 200 may promptly perform MAP decoding for following new fourth data block. Further, regardless of that performing of the other, the first MAP decoder 200, the second MAP decoder 400 or the deinterleaver 500 is acting, after interleaving for the second data block is completed, if writing the interleaved data for the second data block to the second storage unit 120 is completed, the interleaver 300 may perform interleaving for the relevant data block based on the result of performing MAP decoding for the data block stored temporarily in the first storage unit 110.

Thus, the first MAP decoder 200 may perform MAP decoding based on the data block received in the turbo decoder 10 and the operation result for the data block stored temporarily in the fourth storage unit 140 and store temporarily the result of performing MAP decoding to the first storage unit 110, the interleaver 300 may perform interleaving based on the result of performing MAP decoding stored temporarily in the first storage unit 110 and store temporarily the interleaved result (or the result of performing interleaving) to the second storage unit 120, the second MAP decoder 400 may perform MAP decoding based on the interleaved data stored temporarily in the second storage unit 120 and the data that is included in the relevant data block received by turbo decoder 10 and store temporarily the result of performing MAP decoding to the third storage unit 130, the deinterleaver 500 may perform deinterleaving based on the result of performing MAP decoding stored temporarily in the third storage unit 130 and store temporarily the deinterleaved result (or the result of performing deinterleaving) to the fourth storage unit 140, thereby, the first MAP decoder 200, the interleaver 300, the second MAP decoder 400 and the deinterleaver 500 may perform high speed decoding function acting without idle state.

Further, in embodiments of the present invention, it is described that the storage units 110, 120, 130 and 140 are formed between the first MAP decoder 200, the interleaver 300, the second MAP decoder 400 and the deinterleaver 500 respectively, however it is not limited to the description, at least one of (or plurality of) storage unit (at least one storage unit among 110, 120, 130 and 140) may be formed between the first MAP decoder 200, the interleaver 300, the second MAP decoder 400 and the deinterleaver 500.

Thus, if the at least one of storage unit (at least one storage unit among 110, 120, 130 and 140) is formed between the first MAP decoder 200, the interleaver 300, the second MAP decoder 400 and the deinterleaver 500, the operation for the data blocks that are different each other may be processed concurrently on the front block and the rear block of the relevant storage unit in the same timing(or operation time).

Thus, in embodiments of the present invention, the at least one storage unit is formed between the first MAP decoder, the interleaver, the second MAP decoder and the deinterleaver and operation function for the plurality of data blocks that are different each other may is performed in pipelined scheme, thereby the throughput may be improved according to the decoding for the plurality of data blocks.

Further, thus, in embodiments of the present invention, the at least one storage unit is formed between the BM operation unit, the BSM operation unit and the FSM & LLR operation unit which constitutes the MAP decoder and operation function for each of the data blocks that are different each other may is performed in pipelined scheme, thereby its implementation may be easy without performance degradation.

It will be understood by one of ordinary skill in the art that modification and changes for the contents described previously may be possible without departing from the spirit and scope of the present invention. The described embodiments should be considered in a descriptive sense only and not for purpose of limitation for the spirit of the present invention. Therefore, the scope of the invention will be construed by the appended claims, and all the technical spirit within the equivalent scope of the present invention will be construed as being included in the present invention.

What is claimed is:

1. A turbo decoder configured to perform MAP (Maximum A Posteriori) decoding for a plurality of data blocks including encoded noise, comprising:
a first MAP decoder configured to perform MAP decoding for a first data block that is included in the plurality of data blocks;
an interleaver configured to interleave a result of performing MAP decoding for the first data block;
a second MAP decoder configured to perform MAP decoding based on a data included in the first data block and an interleaved data of the first data block;
a deinterleaver configured to deinterleave a result of performing MAP decoding from the second MAP decoder for the first data block; and
at least one storage unit configured to be formed between the first MAP decoder, the interleaver, the second MAP decoder and the deinterleaver.

2. The turbo decoder of claim 1, configured to perform operation concurrently for data blocks which are different each other based on a compartment that is formed on a front and a rear of the at least one storage unit.

3. The turbo decoder of claim 1, wherein the at least one storage unit comprises at least one of:
a first storage unit configured to form between the first MAP decoder and the interleaver;
a second storage unit configured to form between the interleaver and the second MAP decoder;
a third storage unit configured to form between the second MAP decoder and the deinterleaver; and
a fourth storage unit configured to form between the deinterleaver and the first MAP decoder.

4. The turbo decoder of claim 3, wherein the first MAP decoder performs MAP decoding for a second data block that is included in the plurality of data blocks, when the interleaver interleaves a result of performing MAP decoding for the first data block that is stored in the first storage unit.

5. The turbo decoder of claim 3, when the second MAP decoder performs MAP decoding for an interleaved data of the first data block that is stored in the second storage unit, wherein the first MAP decoder performs MAP decoding for a third data block that is included in the plurality of data blocks, and the interleaver interleaves a result of performing MAP decoding for a second data block that is included in the plurality of data blocks stored in the first storage unit.

6. The turbo decoder of claim 3, when the interleaver interleaves a result of performing MAP decoding for the first data block that is stored in the third storage unit, wherein the first MAP decoder performs MAP decoding for a fourth data block that is included in the plurality of data blocks, the interleaver interleaves a result of performing MAP decoding for a third data block that is included in the plurality of data blocks stored in the first storage unit, and the second MAP decoder performs MAP decoding for an interleaved data of a second data block that is included in the plurality of data blocks stored in the second storage unit.

7. The turbo decoder of claim 3, further comprising:
a first delay element configured to output by delaying temporarily a deinterleaved data from the deinterleaver that is stored temporarily in the fourth storage unit;
is a second delay element configured to output by delaying temporarily an interleaved data from the interleaver that is stored temporarily in the second storage unit; and
a third delay element configured to output by delaying temporarily a first data that is included in the first data block and includes encoded noise from an outside.

8. The turbo decoder of claim 7, further comprising:
a first adder configured to add the deinterleaved data from the deinterleaver that is stored temporarily in fourth storage unit and a second data that is included in the first data block and includes encoded noise from the outside, and to transmit the data added by the first adder to the first MAP decoder;
a second adder configured to add a data temporarily delayed by the first delay element and a result of performing MAP decoding from the first MAP decoder for the first data block, and to transmit the data added by the second adder to the first storage unit; and
a third adder configured to add a data temporarily delayed by the second delay element and a result of performing MAP decoding from the second MAP decoder for the first data block, and to transmit the data added by the third adder to the third storage unit.

9. The turbo decoder of claim 8, wherein the first MAP decoder comprises:
a first BM (Branch Matric) operation unit configured to perform BM operation for the data outputted from the first adder and the first data that is included in the first data block and includes encoded noise from the outside;
a fifth storage unit configured to store a result of performing BM operation from the first BM operation unit;
a first BSM (Backward State Matric) operation unit configured to perform BSM operation based on a result of performing BM operation that is stored in the fifth storage unit;
a sixth storage unit configured to store a result of performing BSM operation from the first BSM operation unit; and
a first FSM (Forward State Matric) & LLR (Log Likelihood Ratio) operation unit configured to perform FSM operation and to perform LLR operation based on the result of performing BM operation that is stored in the fifth storage unit and the result of performing BSM operation that is stored in the sixth storage unit.

10. The turbo decoder of claim 8, wherein the second MAP decoder comprises:
a second BM operation unit configured to perform BM operation for the interleaved data stored in the second storage unit and a data delayed by the third delay element; a seventh storage unit configured to store a result of performing BM operation from the second BM operation unit; a second BSM operation unit configured to perform BSM operation based on a result of performing BM operation that is stored in the seventh storage unit;
an eighth storage unit configured to store a result of performing BSM operation from the second BSM operation unit; and
a second FSM & LLR operation unit configured to perform FSM operation and to perform LLR operation based on the result of performing BM operation that is stored in the seventh storage unit and the result of performing BSM operation that is stored in the eighth storage unit.

11. A control method of a turbo decoder for performing MAP decoding for a plurality of data blocks including encoded noise, comprising:
performing, by a first MAP decoder, MAP decoding for a first data block that is included in the plurality of data blocks;
interleaving, by an interleaver, a result of performing MAP decoding for the first data block;
performing, by a second MAP decoder, MAP decoding based on a data included in the first data block and an interleaved data of the first data block;
deinterleaving, by a deinterleaver, a result of performing MAP decoding from the second MAP decoder for the first data block; and
storing the result of performing MAP decoding from the first MAP decoder, the interleaved data from the interleaver, the result of performing MAP decoding from the second MAP decoder and an deinterleaved data from the deinterleaver, by at least one storage unit configured to be formed between the first MAP decoder, the interleaver, the second MAP decoder and the deinterleaver.

12. The control method of claim 11, the interleaving the result of performing MAP decoding for the first data block comprises:
when a first storage unit configured to be formed between the first MAP decoder and the interleaver, interleaving, by the interleaver, the result of performing MAP decoding for the first data block that is stored in the first storage unit; and
performing, by the first MAP decoder, MAP decoding for a second data block that is included in the plurality of data blocks.

13. The control method of claim 11, the performing MAP decoding based on the data included in the first data block and the interleaved data of the first data block comprises:
when a second storage unit configured to be formed between the interleaver and the second MAP decoder, performing, by the second MAP decoder, MAP decoding for the first data block that is stored in the second storage unit; and
performing, by the first MAP decoder, MAP decoding for a second data block that is included in the plurality of data blocks or, interleaving, by the interleaver, a result of performing MAP decoding for the second data block.

14. The control method of claim 11, the deinterleaving the result of performing MAP decoding for the first data block comprises:
when a third storage unit configured to be formed between the second MAP decoder and the deinterleaver, deinterleaving, by the deinterleaver, the first data block that is stored in the third storage unit; and performing by the first MAP decoder MAP decoding for a second data block that is included in the plurality of data blocks, interleaving by the interleaver a result of performing MAP decoding for the second data block, or performing by the second MAP decoder MAP decoding an interleaved data of the data block.
